(19) United States
(12) Patent Application Publication
(10) Pub. No.: US 2017/0051401 A1
(43) Pub. Date: Feb. 23, 2017

(54) METHOD FOR INSTALLING A GAS DIFFUSION DEVICE

(71) Applicant: ION BEAM SERVICES, Peynier (FR)

(72) Inventors: Frank TORREGROSA, Simiane (FR); Laurent ROUX, Marseille (FR)

(73) Assignee: ION BEAM SERVICES, Peynier (FR)

(21) Appl. No.: 15/307,626

(22) PCT Filed: Apr. 29, 2015
(86) PCT No.: PCT/FR2015/000092

§ 371 Date: Oct. 28, 2016

(30) Foreign Application Priority Data
Apr. 30, 2014 (FR) 14/01003

(51) Int. Cl. C23C 16/44; H01J 37/32; C23C 16/455

(52) U.S. Cl. CPC C23C 16/4404; C23C 16/45565; H01J 37/3244; C23C 16/4405

(57) ABSTRACT

The present invention relates to a method of implanting impurities in a part. The method is remarkable in that the part is a gas diffusion device of the showerhead type in the form of a hollow body 1 having a gas admission orifice 2 and an ejection surface 3 provided with a plurality of holes, and the implanting takes place in the ejection surface.

The present invention relates to a method of implanting a gas diffusion device.

The field of the invention is that of treating parts by means of a plasma. This applies for example to so-called plasma-enhanced chemical vapor deposition (PEVCD) machines. This also applies to etching machines, e.g. reactive ion etching (RIE) machines. This also applies to certain machines for plasma immersion ion implantation known under the acronym PIII or under the term “plasma doping”. Such machines have a gas diffusion device of the showerhead type that is in the form of a hollow body with a gas admission orifice and an ejection surface provided with a plurality of miniscule holes. Such a device arranged facing the part for treatment serves to obtain a uniform flow of gas over the part.

By way of example, the parts for treating may be silicon wafers for use in microelectronics, or indeed substrates for use in fabricating flat screens.

By way of indication, various kinds of deposition in widespread use in the field in question are mentioned below:

depositing silicon oxide from tetraethyl orthosilicate (TEOS);

depositing silicon nitride; and

depositing silicon from silane or from dichlorosilane.

It is found that when making such deposits, deposition also takes place on the ejection surface of the gas diffusion device. This leads to the holes in said ejection surface becoming clogged progressively, with the consequences of degrading the uniformity of the flow of gas, of certain particles separating and dropping onto the substrate, and of modifying the rate of deposition.

In order to remedy that problem, in situ cleaning is performed regularly by means of a fluorine-containing plasma, conventionally of NF₃, which etches the unwanted deposit that has appeared on the ejection surface. Such etching is not harmless for the material of the gas diffusion device, which is generally made of an alloy of aluminum or of silicon. The device suffers chemical etching, thereby degrading its surface and possibly changing its shape, in particular the size of the holes present in the ejection surface. As a result of those phenomena, a gas diffusion device can be cleaned, while conserving its initial characteristics, for only a relatively limited number of times. Thereafter, the device needs to be discarded.

It is thus known to protect the gas diffusion device so as to give it greater longevity. For this purpose, titanium nitride is deposited on the ejection surface. That solution presents numerous limitations:

the thickness of the deposit needs to be taken into account when designing the device;

the uniformity of the deposit needs to be very good in the holes in the ejection surface; and

once the deposit has become damaged after being cleaned several times, it is practically impossible to recycle the gas diffusion device.

An object of the present invention is thus to provide a solution that enables the longevity of a gas diffusion device of the showerhead type to be increased significantly.

According to the invention, a method of implanting impurities in a part is remarkable in that the part is a gas diffusion device of the showerhead type in the form of a hollow body having a gas admission orifice and an ejection surface provided with a plurality of holes, and the implanting takes place in the ejection surface.

Doping the ejection surface enables its ability to withstand etching to be increased significantly.

Advantageously, implantation is performed in plasma immersion mode.

In a first option, the device is made of aluminum, and the doping agent is then preferably nitrogen.

In a second option, the device is made of silicon, and the doping agent may then be nitrogen or boron.

According to an additional characteristic of the invention, during implantation, the acceleration voltage lies in the range 10 kilovolts (kV) to 100 kV.

Preferably, the acceleration voltage lies in the range 10 kV to 30 kV.

In a preferred embodiment, the implanted dose lies in the range 2×10¹⁷ per square centimeter (/cm²) to 2×10¹⁸/cm².

The present invention appears below in greater detail in the following description of embodiments given by way of illustration and with reference to the accompanying figures, in which:

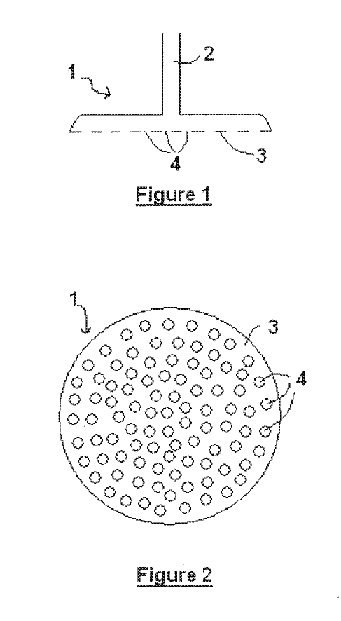

FIG. 1 is a section view of the gas diffusion device; and

FIG. 2 is a view of the ejection surface.

Identical elements that are present in both figures are given the same references in each of them.

With reference to both figures, the gas diffusion device is in the form of a showerhead, in known manner. It is in the form of a hollow body 1 having a gas admission orifice 2 for feeding gas into the hollow body.

The hollow body 1 has an ejection surface 3 with a plurality of miniscule holes 4.

In the invention, the ejection surface is doped with means of impurities by means of ion implantation.

Doping is the action of adding impurities in small quantities to a base material in order to modify its properties. In other words, doping a material consists in introducing atoms of some other material within its matrix.

The atoms of doping material are also referred to as impurities and they are in a dilute phase: their concentration is negligible compared with the concentration of the base material, being of the order of 1/10,000 to a few %.

In a first option, the gas diffusion device is made of aluminum or of aluminum alloy.

Under such circumstances, doping preferably takes place with nitrogen using the plasma immersion implanting technique.

In that technique, implanting the device consists in immersing it in a plasma and in biasing it at several tens of volts to several tens of kilovolts (generally less than 100 kV), so as to create an electric field capable of accelerating the ions of the plasma towards the device so that they become implanted therein. The atoms as implanted in this way are referred to as “dopants”. The bias voltage is generally pulsed.

In the present example, it is naturally the ejection surface that is preferably implanted.

Implanting nitrogen tends to create aluminum nitride. In order to facilitate the formation of this nitride, the temperature during the treatment needs to be relatively high, but not too high so as to avoid degrading the core characteristics of the material. For aluminum, this temperature lies ideally in the range 350° C. to 450° C.

The acceleration voltage advantageously lies in the range 10 kV to 30 kV so as to obtain a penetration depth greater than 70 nanometers (nm), ideally in the range 100 nm to 300 nm.

The implanted dose should lie in the range 2×10¹⁷/cm² to 2×10¹⁸/cm². As a result, a concentration of nitrogen is obtained that is sufficient for creating a layer of nitride that is uniform and of good quality.

Other solutions exist for doping any material. The first that comes to mind is diffusion. Nevertheless, the diffusion technique is poorly adapted to aluminum since it requires a temperature that is higher than that required for implantation. That leads to degradation of the gas diffusion device.

In a second option, the gas diffusion device is made of silicon.

Under such circumstances, the doping could likewise take place using nitrogen, thereby leading to silicon nitride being formed.

The doping could also take place with boron, using a plasma of BF₃ or of B₂H₆.

Only a few solutions are described since it would not be realistic to attempt at a complete list of all possible solutions. Nevertheless, the invention is applicable regardless of the material of the gas diffusion device, and in particular of its ejection surface, and regardless of the nature of the doping agent.

The embodiments of the invention described above have been selected because of their concrete nature. Nevertheless, it is not possible to list exhaustively all embodiments covered by the invention. In particular, any step or any means described may be replaced by an equivalent step or means without going beyond the ambit of the present invention.

1. A method of implanting impurities in a part, the method being characterized in that said part is a gas diffusion device of the showerhead type in the form of a hollow body (1) having a gas admission orifice (2) and an ejection surface (3) provided with a plurality of holes, and the implanting takes place in said ejection surface.

2. A method according to claim 1, characterized in that the implanting is performed in plasma immersion mode.

3. A method according to claim 1, characterized in that the hollow body (1) is made of aluminum.

4. A method according to claim 1, characterized in that said hollow body (1) is made of silicon.

5. A method according to claim 3, characterized in that said impurities are atoms of nitrogen.

6. A method according to claim 4, characterized in that said impurities are atoms of boron.

7. A method according to claim 1, characterized in that the acceleration voltage lies in the range 10 kV to 100 kV.

8. A method according to claim 7, characterized in that the acceleration voltage lies in the range 10 kV to 30 kV.

9. A method according to claim 1, characterized in that the implanted dose lies in the range 2×10¹⁷/cm² to 2×10¹⁸/cm².
